(19) United States
(12) Patent Application Publication
(10) Pub. No.: US 2026/0117371 A1
(43) Pub. Date: Apr. 30, 2026

(54) FILM FORMING METHOD AND FILM FORMING APPARATUS

(71) Applicant: Tokyo Electron Limited, Tokyo (JP)

(72) Inventors: Yumiko KAWANO, Nirasaki City (JP); Shuji AZUMO, Nirasaki City (JP); Tomohiro NAKAGAWA, Hwaseong-si (KR)

(21) Appl. No.: 19/430,860

(22) Filed: Dec. 23, 2025

Related U.S. Application Data
(63) Continuation of application No. PCT/JP2024/018692, filed on May 21, 2024.

(30) Foreign Application Priority Data
Jun. 28, 2023 (JP) JP2023-105853

(51) Int. Cl. C23C 16/40; C23C 16/04; C23C 16/44; C23C 16/50; C23C 16/52; C23C 16/56

(52) U.S. Cl. CPC C23C 16/401; C23C 16/042; C23C 16/4412; C23C 16/50; C23C 16/52; C23C 16/56

(57) ABSTRACT

A film forming method includes: (A) preparing a substrate having a first film and a second film in different regions of a substrate surface; (B) selectively forming a film-formation inhibiting film that inhibits formation of a target film on a surface of the second film; and (C) selectively forming the target film on the surface of the first film by using the film-formation inhibiting film, wherein the target film includes at least silicon (Si) and oxygen (O), and wherein (C) includes: (Ca) supplying a metal catalyst-containing gas to the surface of the substrate to adsorb metal catalysts to the surface of the first film; (Cb) supplying a plasmarized gas to the surface of the substrate to remove at least a portion of the metal catalysts adsorbed to a surface of the film-formation inhibiting film in (Ca); and (Cc) supplying a silanol group-containing gas to the surface of the substrate.

### CROSS-REFERENCE TO RELATED APPLICATION

The application is a Bypass Continuation Application of PCT International Application No. PCT/JP2024/018692, filed on May 21, 2024 and designating the United States, the international application being based upon and claiming the benefit of priority from Japanese Patent Application No. 2023-105853, filed on Jun. 28, 2023, the entire content of which is incorporated herein by reference.

### TECHNICAL FIELD

The present disclosure relates to a film forming method and a film forming apparatus.

### BACKGROUND

A film forming method described in Patent Document 1 includes, selectively forming a polyimide film or a self-assembled monolayer on a surface of a metal film relative to a surface of a dielectric film, and selectively forming a silicon oxide film on the surface of the dielectric film relative to the surface of the metal film, sequentially in this order. The silicon oxide film is formed using metal catalysts and silanol.

### PRIOR ART DOCUMENT

### Patent Document

Patent Document 1: U.S. Patent Application Publication No. 2021/301392

### SUMMARY

A film forming method according to the present disclosure includes: (A) preparing a substrate having a first film and a second film, which is made of a material different from that of the first film, in different regions of a surface of the substrate; (B) selectively forming a film-formation inhibiting film that inhibits formation of a target film on a surface of the second film relative to a surface of the first film; and (C) selectively forming the target film on the surface of the first film relative to the surface of the second film by using the film-formation inhibiting film, wherein the target film includes at least silicon (Si) and oxygen (O), and wherein (C) includes: (Ca) supplying a metal catalyst-containing gas to the surface of the substrate to adsorb metal catalysts to the surface of the first film; (Cb) after (Ca), supplying a plasmarized gas to the surface of the substrate to remove at least a portion of the metal catalysts adsorbed to a surface of the film-formation inhibiting film in (Ca); and (Cc) after (Cb), supplying a silanol group-containing gas to the surface of the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to an embodiment.

FIG. 2 is a flowchart illustrating an example of a subroutine of S105.

FIG. 3 is a flowchart illustrating an example of a subroutine of S106.

FIG. 4A is a cross-sectional view illustrating a first example of S101.

FIG. 4B is a cross-sectional view illustrating a first example of S102 and S103.

FIG. 4C is a cross-sectional view illustrating a first example of S104.

FIG. 4D is a cross-sectional view illustrating a first example of S105a.

FIG. 4E is a cross-sectional view illustrating a first example of S105b.

FIG. 4F is a cross-sectional view illustrating a first example of S105c.

FIG. 5A is a cross-sectional view illustrating a second example of S101.

FIG. 5B is a cross-sectional view illustrating a second example of S102 and S103.

FIG. 5C is a cross-sectional view illustrating a second example of S104.

FIG. 5D is a cross-sectional view illustrating a second example of S105a.

FIG. 5E is a cross-sectional view illustrating a second example of S105b.

FIG. 5F is a cross-sectional view illustrating a second example of S105c.

FIG. 6A is a cross-sectional view illustrating a third example of S101.

FIG. 6B is a cross-sectional view illustrating a third example of S102 and S103.

FIG. 6C is a cross-sectional view illustrating a third example of S104.

FIG. 6D is a cross-sectional view illustrating a third example of S105a.

FIG. 6E is a cross-sectional view illustrating a third example of S105b.

FIG. 6F is a cross-sectional view illustrating a third example of S105c.

FIG. 7 is a plan view illustrating a film forming apparatus according to an embodiment.

FIG. 8 is a cross-sectional view illustrating an example of a first processor in FIG. 7.

FIG. 9 is a diagram illustrating X-ray photoelectron spectroscopy (XPS) spectra of substrate surfaces obtained in Examples 4 and 5.

### DETAILED DESCRIPTION

Reference will now be made in detail to various embodiments, examples of which are shown in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each drawing, the same or corresponding components are denoted by the same reference numerals, and the description thereof may be omitted.

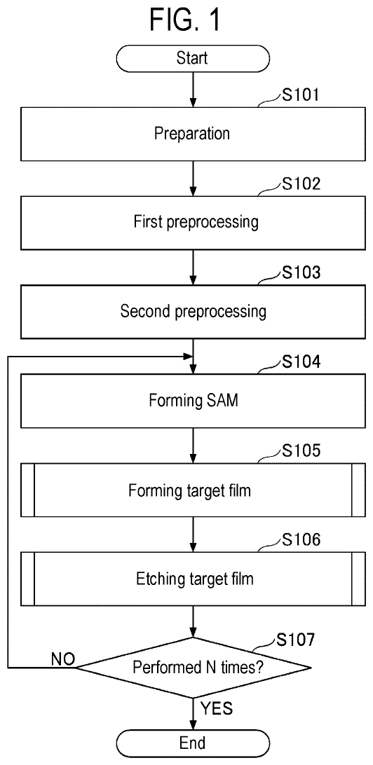

A film forming method according to an embodiment will now be described with reference mainly to FIGS. 1 to 6F. The film forming method includes, for example, steps S101 to S107 shown in FIG. 1. The film forming method may include at least steps S101, S104, and S105 and may not include, for example, steps S102, S103, S106, and S107. The film forming method may also include steps other than steps S101 to S107 shown in FIG. 1.

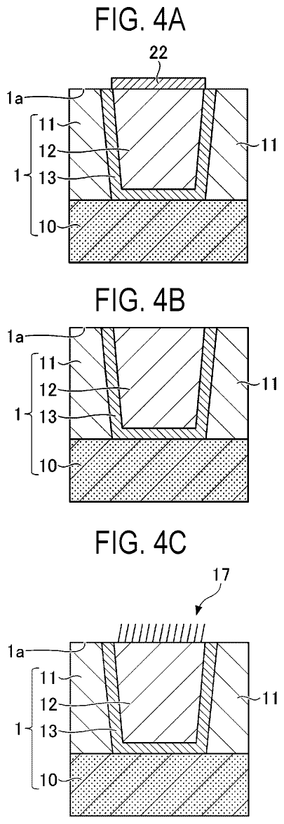

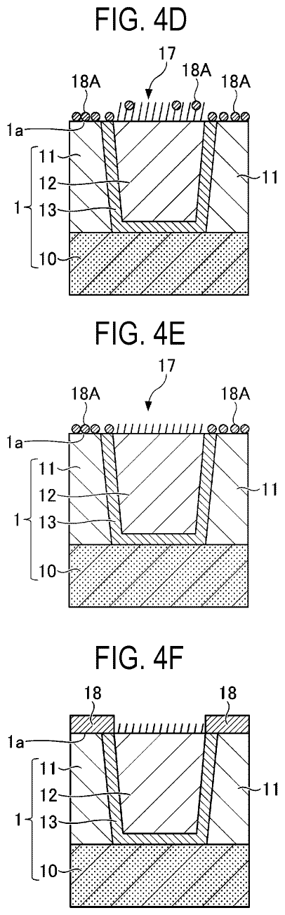

Step S101 includes preparing a substrate 1 as shown in FIG. 4A. The substrate 1 includes a base substrate 10. The base substrate 10 is, for example, a silicon wafer, a compound semiconductor wafer, or a glass substrate. The substrate 1 has an insulating film 11 and a conductive film 12 in different regions of a substrate surface 1a. The substrate surface 1a is, for example, an upper surface of the substrate 1. The insulating film 11 and the conductive film 12 are formed over the base substrate 10. Another functional film may be formed between the base substrate 10 and the insulating film 11 or between the base substrate 10 and the conductive film 12. The insulating film 11 is an example of a first film, and the conductive film 12 is an example of a second film. Materials of the first film and the second film are not particularly limited.

The insulating film 11 is, for example, an interlayer insulating film. The interlayer insulating film may be a low dielectric (low-k) film. The insulating film 11 is, for example, a SiO film, a SiN film, a SiOC film, a SiON film, or a SiOCN film, but is not being particularly limited thereto. Here, the SiO film refers to a film containing silicon (Si) and oxygen (O). An atomic ratio of Si to O in the SiO film is usually 1:2, but is not limited to 1:2. Similarly, each of the SiN film, the SiOC film, the SiON film, and the SiOCN film refers to a film containing corresponding elements and is not limited to a stoichiometric ratio. The insulating film 11 has a recess in the substrate surface 1a. The recess is a trench, a contact hole, or a via hole.

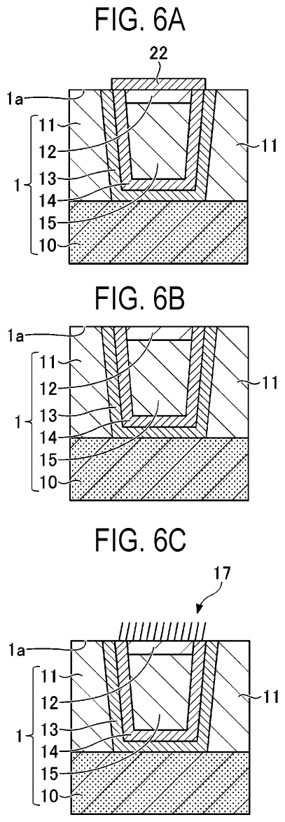

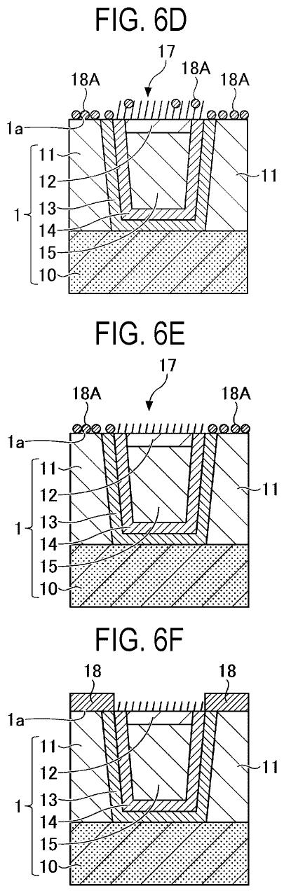

The conductive film 12 fills, for example, the recess of the insulating film 11. The conductive film 12 is, for example, a metal film. The metal film is, for example, a Cu film, a Co film, a Ru film, a W film, or a Mo film. The conductive film 12 may be a cap film. In other words, as shown in FIG. 6A, a second conductive film 15 may be embedded in the recess of the insulating film 11, and the second conductive film 15 may be covered with the conductive film 12. The second conductive film 15 is made of a metal different from that of the conductive film 12. For example, the second conductive film 15 is a Cu film, and the conductive film 12 (cap film) is a Co film or a Ru film.

The substrate 1 may further include a third film in the substrate surface 1a. The third film is, for example, a barrier film 13. The barrier film 13 is formed between the insulating film 11 and the conductive film 12, and suppresses metal diffusion from the conductive film 12 to the insulating film 11. The barrier film 13 is, for example, a TaN film or a TiN film, but is not limited thereto. Here, the TiN film refers to a film containing titanium (Ti) and nitrogen (N). An atomic ratio of Ti to N in the TiN film is usually 1:1, but is not limited to 1:1. Similarly, the TaN film refers to a film containing corresponding elements and is not limited to a stoichiometric ratio.

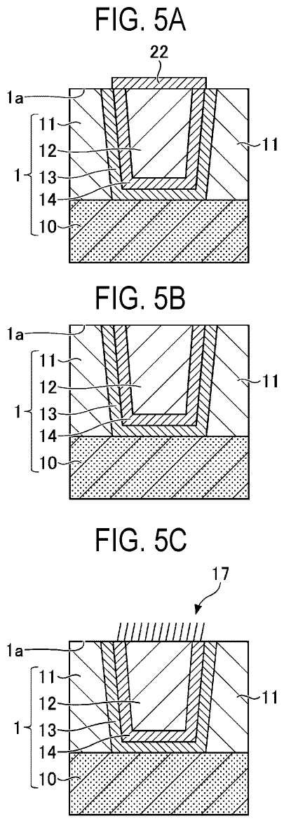

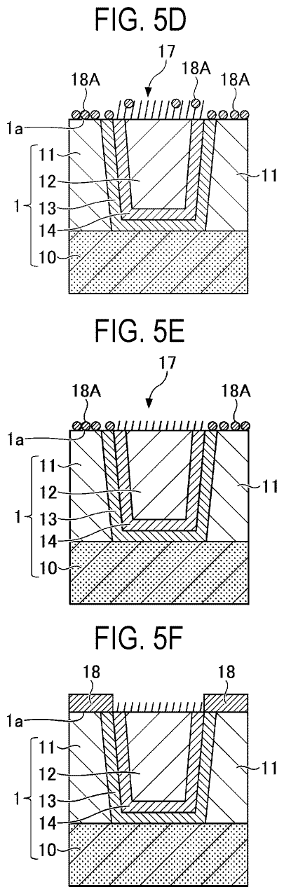

The substrate 1 may further include a fourth film in the substrate surface 1a. The fourth film is, for example, a liner film 14 (see FIGS. 5A and 6A). The liner film 14 is formed between the conductive film 12 and the barrier film 13. The liner film 14 is formed on the barrier film 13, and assists in formation of the conductive film 12. The conductive film 12 is formed on the liner film 14. For example, the conductive film 12 is a Cu film, and the liner film 14 is a Co film or a Ru film.

As shown in FIGS. 4A, 5A, and 6A, a contaminant 22 may exist on the substrate surface 1a. The contaminant 22 is, for example, a metal oxide. The metal oxide is formed by, for example, a reaction between the conductive film 12 and the atmosphere. The contaminant 22 may also be an organic material. The organic material is, for example, a deposit containing carbon and is attached during a processing of the substrate 1. The organic material may be layered.

Step S102 includes performing a first preprocessing of removing the contaminant 22 from the substrate surface 1a, as shown in FIGS. 4B, 5B, and 6B. In the first preprocessing, a cleaning gas is supplied to the substrate surface 1a. A plurality of cleaning gases may be supplied sequentially. In the present embodiment, a first cleaning gas, a second cleaning gas, and a third cleaning gas are supplied sequentially.

The first cleaning gas includes at least a reducing gas such as H₂ gas and may include, in addition to the reducing gas, a nitrogen-containing gas such as N₂ gas. The first cleaning gas may be plasmarized and then supplied to the substrate surface 1a.

An example of processing conditions in a case of using the first cleaning gas is as follows.
Flow rate of H₂ gas: 50 sccm to 5,000 sccm
Flow rate of N₂ gas: 50 sccm to 10,000 sccm
Flow rate of Ar gas: 20 sccm to 10,000 sccm
Ratio of H₂ gas in the first cleaning gas: 10 vol % to 60 vol %
Ratio of N₂ gas in the first cleaning gas: 10 vol % to 80 vol %
Power supply frequency for plasma generation: 10 MHz to 100 MHz
Power for plasma generation: 50 W to 400 W
Processing time: 5 seconds to 120 seconds
Processing temperature (substrate temperature): 80 degrees C. to 350 degrees C.
Processing pressure: 50 Pa to 2,000 Pa.

The second cleaning gas includes an oxygen-containing gas. The oxygen-containing gas includes at least one selected from the group consisting of O₂ gas, O₃ gas, H₂O gas, NO gas, NO₂ gas, and N₂O gas. The oxygen-containing gas is supplied to the substrate surface 1a without being plasmarized.

An example of processing conditions in a case of using the second cleaning gas is as follows.
Flow rate of O₂ gas: 100 sccm to 2,000 sccm
Processing time: 10 seconds to 5 minutes
Processing temperature (substrate temperature): 80 degrees C. to 350 degrees C.
Processing pressure: 50 Pa to 665 Pa.

The third cleaning gas includes at least one selected from the group consisting of, for example, a carboxylic acid compound, a phosphonic acid compound, a nitro compound, and a thiol compound. The carboxylic acid compound is represented by a general formula of “R—COOH.” The phosphonic acid compound is represented by a general formula of “R—P(═O)(OH)₂.” The nitro compound is represented by a general formula of “R—NO₂.” The thiol compound is represented by a general formula of “R—SH.”

In the general formulas described above, R is, for example, a hydrocarbon group, or a hydrocarbon group in which at least a portion of hydrogen is replaced with fluorine. Specifically, for example, R is “CF₃—(CF₂)_{X}—,” “CF₃—(CF₂)_{X}—CH₂—CH₂—,” or “CH₃—(CH₂)_{X}—.” X is an integer from 1 to 17. Specific examples of the carboxylic acid compound include PFBA (CF₃(CF₂)₂COOH), formic acid (HCOOH), acetic acid (CH₃COOH), propionic acid (CH₃CH₂COOH), and octanoic acid (CH₃(CH₂)₆COOH). A specific example of the nitro compound includes PFNO (CF₃(CF₂)₅CH₂CH₂NO₂).

An example of processing conditions in a case of using the third cleaning gas is as follows.
Flow rate of PFBA gas: 10 sccm to 100 sccm
Processing time: 30 seconds to 10 minutes
Processing temperature (substrate temperature): 80 degrees C. to 350 degrees C.
Processing pressure: 100 Pa to 300 Pa.

Step S103 includes performing a second preprocessing of removing residues of the cleaning gas supplied in step S102. The residues of the cleaning gas are mainly organic materials. In the second preprocessing, a plasmarized gas is supplied to the substrate surface 1a. The gas includes at least a reducing gas such as H₂ gas and may include, in addition to the reducing gas, a nitrogen-containing gas such as N₂ gas. Since the processing conditions of step S103 are the same as the processing conditions in the case of using the first cleaning gas in step S102, a description thereof is omitted.

Step S104 includes selectively forming a self-assembled monolayer 17 on a surface of the conductive film 12 relative to a surface of the insulating film 11 as shown in FIGS. 4C, 5C, and 6C. Hereinafter, the self-assembled monolayer 17 may be referred to as the SAM 17. The SAM 17 is formed by supplying an organic compound gas to the substrate surface 1a. The organic compound gas is a raw material gas of the SAM 17.

The raw material gas of the SAM 17 is not particularly limited, but includes, for example, a thiol compound. Specific examples of the thiol compound include CF₃(CF₂)₅CH₂CH₂SH (1H, 1H, 2H, 2H-perfluorooctanethiol: PFOT) and CH₃(CH₂)₅SH (hexanethiol: HT). The thiol compound is more likely to be chemically adsorbed to the surface of the conductive film 12 than to the surface of the insulating film 11. Therefore, the SAM 17 is selectively formed on the surface of the conductive film 12 relative to the surface of the insulating film 11. The SAM 17 is hardly formed on the surface of the insulating film 11. The SAM 17 may be formed not only on the surface of the conductive film 12 but also on a surface of the liner film 14, as shown in FIGS. 5C and 6C.

The raw material gas of the SAM 17 is not limited to the thiol compound. The raw material gas of the SAM 17 may include a phosphonic acid compound, a carboxylic acid compound, or a nitro compound. The first cleaning gas and the raw material gas of the SAM 17 may include the same organic compound or different organic compounds. However, by using the same organic compound, costs can be reduced, for example, reduction in the number of chambers.

The raw material gas of the SAM 17 may include an olefin compound or an organic silane compound. The olefin compound is represented by a general formula of “R—CH═CH₂”. The organic silane compound is, for example, a trichlorosilane compound, a methoxysilane compound, or an ethoxysilane compound. The trichlorosilane organic compound is represented by a general formula of “R—SiCl₃.” The methoxysilane organic compound is represented by a general formula of “R—Si(OCH₃)₃.” The ethoxysilane organic compound is represented by a general formula of “R—Si(OCH₂CH₃)₃.”

An example of processing conditions of step S104 is as follows.
Flow rate of HT gas: 50 sccm to 200 sccm
Processing time: 3 seconds to 120 seconds
Processing temperature: 80 degrees C. to 350 degrees C.
Processing pressure: 50 Pa to 4,000 Pa.

Further, step S104 may include selectively forming a film-formation inhibiting film, which inhibits formation of a target film, on a surface of the second film relative to a surface of the first film. The insulating film 11 is an example of the first film, the conductive film 12 is an example of the second film, and the SAM 17 is an example of the film-formation inhibiting film. The film-formation inhibiting film is not limited to the SAM and may be, for example, a graphene-containing film.

Step S105 includes selectively forming a second insulating film 18 on the surface of the insulating film 11 relative to the surface of the conductive film 12 by using the SAM 17, as shown in FIGS. 4D to 4F, 5D to 5F, and 6D to 6F. The second insulating film 18 is an example of the target film.

The second insulating film 18 is, for example, a SiO film containing at least silicon (Si) and oxygen (O). The SiO film is formed by using, for example, a metal catalyst-containing gas and a silanol group-containing gas. The metal catalyst-containing gas contains metal catalysts. The metal catalysts promote a dehydration condensation reaction of a silanol group contained in the silanol group-containing gas. The SiO film is formed by the dehydration condensation reaction of the silanol group. The SiO film may include, in addition to silicon (Si) and oxygen (O), the metal catalysts.

The metal catalyst-containing gas may be an organometallic compound gas. Specifically, examples of the organometallic compound gas include an organic aluminum compound gas and an organic titanium compound gas. The organic aluminum compound gas is, for example, trimethylaluminum (TMA) gas, triethylaluminum (TEA) gas, dimethylaluminum chloride gas, or dimethylaluminum isopropoxide (DMAI). The organic titanium compound gas is, for example, tetrakis(dimethylamino)titanium (TDMAT) gas.

The silanol group-containing gas is not particularly limited but, for example, tris(tert-pentoxy)silanol (TPSOL), triethylsilanol, methylbis(tert-pentoxy)silanol, or tris(tert-butoxy)silanol (TBSOL) is used.

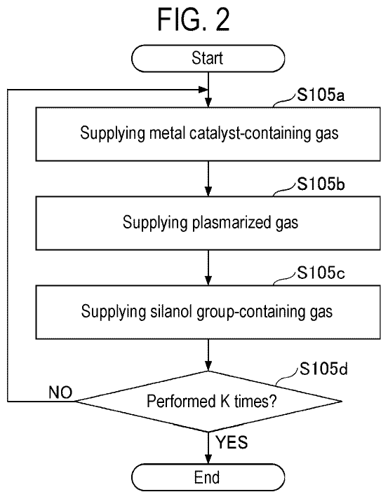

Step S105 includes, for example, supplying the metal catalyst-containing gas (step S105a), supplying a plasmarized gas (step S105b), and supplying the silanol group-containing gas (step S105c) K times (where K is an integer of 1 or more), for example, as shown in FIG. 2. K may be an integer of 2 or more, and steps S105a to S105c may be repeatedly performed a plurality of times. K may be 1 to 5. The present embodiment differs from Patent Document 1 in that step S105 includes step S105b.

Step S105a includes, as shown in FIGS. 4D, 5D, and 6D, supplying the metal catalyst-containing gas to the substrate surface 1a so that metal catalysts 18A are adsorbed to the surface of the insulating film 11. The SAM 17 inhibits the metal catalysts 18A from being adsorbed to the surface of the conductive film 12. However, although smaller in adsorption amount (number) compared to the surface of the insulating film 11, the metal catalysts 18A may be adsorbed to a surface of the SAM 17. The same applies to a case in which, for example, the graphene-containing film is used as the film-formation inhibiting film.

An example of processing conditions of step S105a is as follows.
Flow rate of TMA gas: 10 sccm to 100 sccm
Processing time: 0.05 seconds to 100 seconds
Processing temperature: 80 degrees C. to 350 degrees C.
Processing pressure: 133 Pa to 1,200 Pa.

Step S105b includes, as shown in FIGS. 4E, 5E, and 6E, supplying a plasmarized gas to the substrate surface 1a to remove at least a portion of the metal catalysts 18A adsorbed to the surface of the SAM 17. The plasmarized gas removes the at least the portion (specifically all) of the metal catalysts 18A adsorbed to the surface of the SAM 17 by removing at least a portion (specifically only a portion) of the SAM 17.

The plasmarized gas is, for example, H₂ gas, a noble gas, or a mixed gas of H₂ gas and a noble gas. The noble gas is, for example, Ar gas or He gas. Plasma desorbs the metal catalysts 18A adsorbed to the surface of the SAM 17 by decomposing the surface of the SAM 17. At this time, a portion of the metal catalysts 18A adsorbed to the surface of the insulating film 11 may be desorbed due to contact with the plasmarized gas. However, since the adsorption amount (number) of the metal catalysts 18A to the surface of the insulating film 11 is large, even when some of the metal catalysts 18A are desorbed, an amount of the metal catalysts 18A required to promote the dehydration condensation reaction of the silanol group contained in the silanol group-containing gas can be secured.

According to the present embodiment, after supplying the metal catalyst-containing gas (step S105a) and before supplying the silanol group-containing gas (step S105c), at least a portion (specifically all) of the metal catalysts 18A adsorbed to the surface of the SAM 17 is removed. Thus, it is possible to suppress deposition of the second insulating film 18 on the surface of the conductive film 12, to increase an opening width of the second insulating film 18, and to reduce a wiring resistance of the substrate 1.

In the case in which the graphene-containing film, instead of the SAM 17, is formed in step S104 as the film-formation inhibiting film that inhibits formation of the second insulating film 18, a plasmarized gas is also supplied to the substrate surface 1a to remove at least a portion (specifically all) of the metal catalysts 18A adsorbed to the surface of the graphene-containing film. Thus, it is possible to suppress deposition of the second insulating film 18 on the surface of the conductive film 12, to increase the opening width of the second insulating film 18, and to reduce the wiring resistance of the substrate 1.

An example of processing conditions of step S105b is as follows.
Flow rate of H₂ gas: 200 sccm to 3,000 sccm
Flow rate of Ar gas: 100 sccm to 6,000 sccm
Ratio of H₂ gas in the mixed gas of H₂ gas and Ar gas: 0 vol % to 90 vol %
Power supply frequency for plasma generation: 10 MHz to 60 MHz
Power for plasma generation: 50 W to 600 W
Processing time: 2 seconds to 120 seconds
Processing temperature: 80 degrees C. to 350 degrees C.
Processing pressure: 50 Pa to 1,200 Pa.

Step S105c includes supplying the silanol group-containing gas to the substrate surface 1a, as shown in FIGS. 4F, 5F, and 6F. The metal catalysts 18A adsorbed to the surface of the insulating film 11 promote the dehydration condensation reaction of the silanol group contained in the silanol group-containing gas. As a result, the second insulating film 18 is selectively formed on the surface of the insulating film 11 relative to the surface of the conductive film 12.

An example of the processing conditions of step S105c is as follows. TPSOL gas is supplied by vaporizing TPSOL liquid.
Flow rate of TPSOL gas: 0.1 g/min to 0.5 g/min
Processing time: 3 seconds to 120 seconds
Processing temperature: 80 degrees C. to 350 degrees C.
Processing pressure: 133 Pa to 1,200 Pa.

In step S105, after supplying the metal catalyst-containing gas (step S105a) and before supplying the silanol group-containing gas (step S105c), the SAM 17 may remain on the surface of the conductive film 12. The remaining SAM 17 can inhibit adsorption of the silanol group-containing gas. Further, the remaining SAM 17 is also helpful in step S106.

However, although not shown, a blocking performance of the SAM 17 is not perfect, and the second insulating film 18 may protrude laterally from the surface of the insulating film 11 and thus cover a portion of the surface of the conductive film 12. In this case, the opening width of the second insulating film 18 is narrowed, and the wiring resistance of the substrate 1 is increased. Therefore, the substrate processing method may include step S106.

Step S106 includes preferentially etching a portion of the second insulating film 18 with respect to another portion of the second insulating film 18. The portion of the second insulating film 18 includes a portion of the second insulating film 18 deposited on the surface of the conductive film 12, and includes a portion of the SAM 17. Thus, the portion of the second insulating film 18 is more defective and has a higher etching rate, compared to the another portion of the second insulating film 18.

Even in the case in which the graphene-containing film or the like, instead of the SAM 17, is formed in step S104 as the film-formation inhibiting film that inhibits the formation of the second insulating film 18, the portion of the second insulating film 18 has a higher etching rate compared to the another portion of the second insulating film 18. The reason is because the second insulating film (the portion of the second insulating film 18) in a vicinity of the film-formation inhibiting film is inhibited from growing by affection of the film-formation inhibiting film, and thus is reduced in thickness or density.

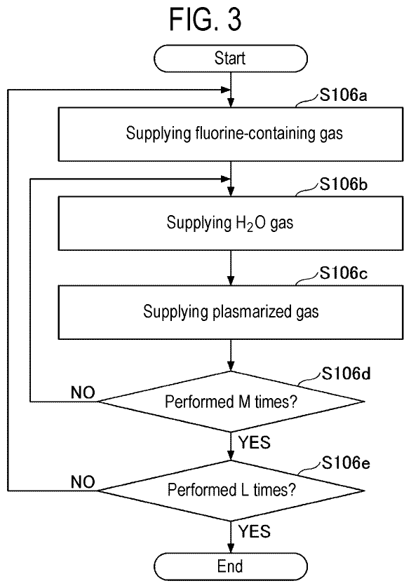

Step S106 includes, for example, supplying a fluorine-containing gas (step S106a), supplying H₂O gas (step S106b), and supplying a plasmarized gas (step S106c), as shown in FIG. 3. Step S106 includes performing steps S106b and S106c a set number of times (M times). M may be an integer of 2 or more, and steps S106b and S106c described above may be repeatedly performed a plurality of times. Further, step S106 includes performing step S106a once and then steps S106b and S106c M times a set number of times (L times). L may be an integer of 2 or more, and steps S106a to S106c may be repeatedly performed a plurality of times.

Step S106a includes, although not shown, supplying a fluorine-containing gas to the surface of the second insulating film 18 to form a fluorine-containing layer on the surface of the second insulating film 18. The fluorine-containing layer may be deposited not only on the surface of the second insulating film 18 but also on the surface of the SAM 17. Alternatively, instead of forming the fluorine-containing layer on the surface of the second insulating film 18, fluorine may be adsorbed to the surface of the second insulating film 18.

The fluorine-containing gas is, for example, a mixed gas of HF gas and NH₃ gas. The fluorine-containing layer is formed by a reaction between the mixed gas of HF gas and NH₃ gas and the second insulating film 18. In the case in which the second insulating film 18 is a film containing silicon (Si) and oxygen (O), the fluorine-containing layer includes ammonium hexafluorosilicate ((NH₄)₂SiF₆).

The fluorine-containing layer only needs to be formed to an extent that an unnecessary portion of the second insulating film 18 (a portion deposited on the surface of the conductive film 12) can be etched in steps S106b and S106c. To prevent excessive formation of the fluorine-containing layer, step S106a may be performed at a lower temperature than steps S106b and S106c. A temperature of the substrate 1 in step S106a is, for example, 50 degrees C. to 100 degrees C.

In the present embodiment, although the fluorine-containing gas is a mixed gas of HF gas and NH₃ gas, the fluorine-containing gas does not necessarily include NH₃ gas and may include HF gas only. In this case, instead of forming the fluorine-containing layer on the surface of the second insulating film 18, fluorine may be adsorbed to the surface of the second insulating film 18.

An example of processing conditions of step S106a is as follows.
Flow rate of HF gas: 10 sccm to 100 sccm
Flow rate of NH₃ gas: 10 sccm to 100 sccm
Processing time: 0.05 seconds to 100 seconds
Processing temperature: 50 degrees C. to 100 degrees C.
Processing pressure: 133 Pa to 1,200 Pa.

Step S106b includes supplying H₂O gas to the surface of the second insulating film 18 to generate hydrogen fluoride. The hydrogen fluoride is generated by a reaction of the fluorine-containing layer and the H₂O gas. Alternatively, the hydrogen fluoride may be generated by a reaction of fluorine adsorbed to the surface of the second insulating film 18 instead of the fluorine-containing layer, and the H₂O gas. In step S106b, H₂O₂ gas may also be used, in addition to the H₂O gas. In step S106b, the H₂O gas may not be plasmarized. In this case, generation of oxygen plasma and oxidation of the conductive film 12 can be prevented.

An example of processing conditions of step S106b is as follows.
Flow rate of H₂O gas: 10 sccm to 500 sccm
Processing time: 0.1 seconds to 120 seconds
Processing temperature: 80 degrees to 350 degrees C.
Processing pressure: 50 Pa to 1,200 Pa.

Step S106c includes supplying a plasmarized gas to the surface of the second insulating film 18. By sequentially performing steps S106b and S106c, it is possible to prevent plasmarization of the H₂O gas, generation of oxygen plasma, and oxidation of the conductive film 12.

In step S106c, the plasmarized gas may not contain an oxygen-based gas in order to prevent generation of oxygen plasma. The plasmarized gas is, for example, H₂ gas, a noble gas, or a mixed gas of H₂ gas and a noble gas. The noble gas is, for example, Ar gas or He gas. Plasma promotes decomposition of the fluorine-containing layer or desorption of fluorine, and promotes generation of hydrogen fluoride. As a result, etching of the second insulating film 18 by the hydrogen fluoride can be promoted.

According to the present embodiment, a portion of the second insulating film 18 is preferentially etched with respect to another portion of the second insulating film 18. An unnecessary portion of the second insulating film 18 (the portion deposited on the surface of the conductive film 12) is etched, whereas a necessary portion of the second insulating film 18 (a portion deposited on the surface of the insulating film 11) is hardly etched. Therefore, the unnecessary portion of the second insulating film 18 can be selectively removed.

An example of processing conditions of step S106c is as follows.
Flow rate of H₂ gas: 200 sccm to 3,000 sccm
Flow rate of Ar gas: 100 sccm to 6,000 sccm
Ratio of H₂ gas in mixed gas of H₂ gas and Ar gas: 0 vol % to 90 vol %
Power supply frequency for plasma generation: 10 MHz to 60 MHz
Power for plasma generation: 50 W to 600 W
Processing time: 2 seconds to 120 seconds
Processing temperature: 80 degrees C. to 350 degrees C.
Processing pressure: 50 Pa to 1,200 Pa.

Step S106d includes checking whether steps S106b and S106c have been executed the set number of times (M times). When the execution number has not reached the set number of times (M times), the second insulating film 18 is insufficiently etched, and therefore, steps S106b and S106c are performed again. On the other hand, when the execution number has reached the set number of times (M times), the second insulating film 18 is sufficiently etched, and therefore, subsequent processing of step S106e is performed.

The set number of times (M times) in step S106d is, for example, 1 to 50 times, and specifically 2 to 50 times. When M is an integer of 2 or more, steps S106b and S106c are repeatedly performed a plurality of times. Thus, decomposition of the fluorine-containing layer or desorption of fluorine can proceed gradually, and hydrogen fluoride can be generated over a long period of time. As a result, the opening width of the second insulating film 18 can be increased, and the wiring resistance of the substrate 1 can be reduced.

Step S106e includes checking whether the performing step S106a a single time and then steps S106b and S106c M times has been executed the set number of times (L times). When the execution number has not reached the set number of times (L times), the second insulating film 18 is insufficiently etched, and therefore steps S106a to S106c are performed again. On the other hand, when the execution number has reached the set number of times (L times), the second insulating film 18 is sufficiently etched, and subsequent processing of step S107 is performed.

The set number of times (L times) in step S106e is, for example, 1 to 50 times, and specifically 2 to 50 times. When L is an integer of 2 or more, steps S106a to S106c are repeatedly performed a plurality of times. Thus, the fluorine-containing layer 19 can be regenerated and hydrogen fluoride can be generated over a long period of time. As a result, the opening width of the second insulating film 18 can be increased, and the wiring resistance of the substrate 1 can be reduced. In this case, the wiring resistance includes a wiring resistance of a via passing through layers, and a yield of good via can also be improved by the increased opening width.

Step S107 includes checking whether steps S104 to S106 have been executed a set number of times (N times). When the execution number has not reached the set number of times (N times), a thickness of the second insulating film 18 has not yet reached a target thickness, and therefore steps S104 to S106 are performed again. On the other hand, when the execution number has reached the set number of times (N times), the thickness of the second insulating film 18 has reached the target thickness, and therefore the process ends.

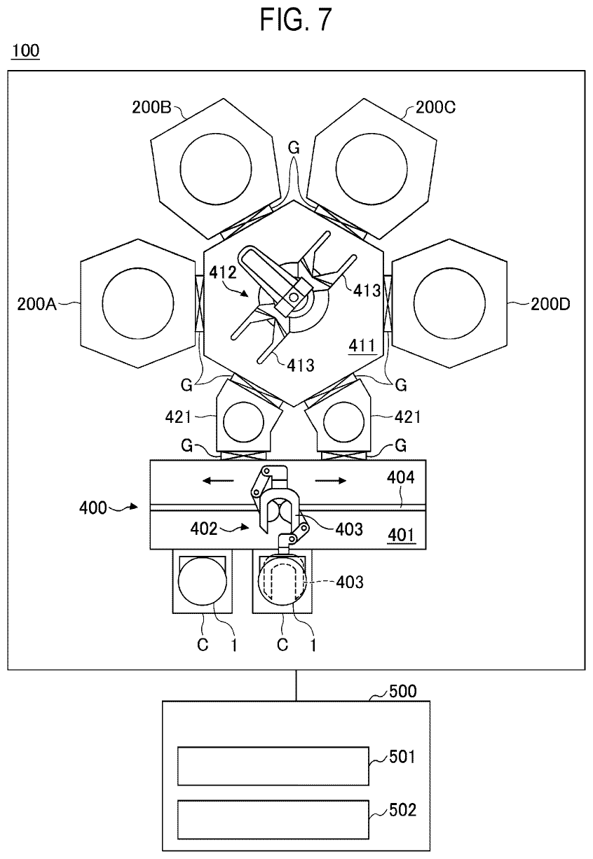

Next, a film forming apparatus 100 for performing the above-described film forming method will be described with reference to FIG. 7. As shown in FIG. 7, the film forming apparatus 100 includes a first processor 200A, a second processor 200B, a third processor 200C, a fourth processor 200D, a transfer portion 400, and a controller 500. The first processor 200A performs steps S102 and S103 in FIG. 1. The second processor 200B performs step S104 in FIG. 1. The third processor 200C performs S105 in FIG. 1. The fourth processor 200D performs step S106 in FIG. 1. The first processor 200A, the second processor 200B, the third processor 200C, and the fourth processor 200D may have the same structure or different structures. The first processor 200A may perform all of steps S102 to S106 in FIG. 1. The transfer portion 400 transfers the substrate 1 to the first processor 200A, the second processor 200B, the third processor 200C, and the fourth processor 200D. The controller 500 controls the first processor 200A, the second processor 200B, the third processor 200C, the fourth processor 200D, and the transfer portion 400.

The transfer portion 400 includes a first transfer chamber 401 and a first transferrer 402. An internal atmosphere of the first transfer chamber 401 is atmospheric atmosphere. The first transferrer 402 is provided inside the first transfer chamber 401. The first transferrer 402 includes arms 403 each holding the substrate 1, and travels along a rail 404. The rail 404 extends in an arrangement direction of carriers C.

The transfer portion 400 further includes a second transfer chamber 411 and a second transferrer 412. An internal atmosphere of the second transfer chamber 411 is a vacuum atmosphere. The second transferrer 412 is provided inside the second transfer chamber 411. The second transferrer 412 includes arms 413 each holding the substrate 1. The arms 413 are disposed to be movable in a vertical direction and a horizontal direction and to be rotatable around a vertical axis. The first processor 200A, the second processor 200B, the third processor 200C, and the fourth processor 200D are connected to the second transfer chamber 411 via different gate valves G.

The transfer portion 400 further includes load lock chambers 421 between the first transfer chamber 401 and the second transfer chamber 411. An internal atmosphere of each of the load lock chambers 421 is switched between a vacuum atmosphere and atmospheric atmosphere by a pressure regulator which is not shown. Thus, an inside of the second transfer chamber 411 can always be maintained at the vacuum atmosphere. Further, it is possible to suppress a gas from flowing into the second transfer chamber 411 from the first transfer chamber 401. Gate valves G are provided between the first transfer chamber 401 and the load lock chambers 421 and between the second transfer chamber 411 and the load lock chambers 421.

The controller 500 is, for example, a computer and includes a calculator 501 such as a central processing unit (CPU) and a storage 502 such as a memory. The storage 502 stores programs that control various processes executed in the film forming apparatus 100. The controller 500 controls operations of the film forming apparatus 100 by causing the calculator 501 to execute the programs stored in the storage 502. The controller 500 controls the first processor 200A, the second processor 200B, the third processor 200C, the fourth processor 200D, and the transfer portion 400 to perform the above-described film forming method.

The controller 500 includes electronic circuits such as a CPU, a field programmable gate array (FPGA), and an application specific integrated circuit (ASIC), and executes various control operations described in the present disclosure by executing instruction codes stored in the memory or by being circuit-designed for a special purpose.

Next, an operation of the film forming apparatus 100 will be described. First, the first transferrer 402 takes the substrate 1 out of the carrier C, transfers the substrate 1 to the load lock chamber 421, and then is retracted from the load lock chamber 421. The internal atmosphere of the load lock chamber 421 is then switched from atmospheric atmosphere to the vacuum atmosphere. Thereafter, the second transferrer 412 takes the substrate 1 out of the load lock chamber 421 and then transfers the substrate 1 to the first processor 200A.

Subsequently, the first processor 200A performs steps S102 and S103. Thereafter, the second transferrer 412 takes the substrate 1 out of the first processor 200A and then transfers the substrate 1 to the second processor 200B. During this time, since an ambient atmosphere of the substrate 1 can be maintained at the vacuum atmosphere, unintended oxidation of the substrate 1 can be suppressed.

Subsequently, the second processor 200B performs step S104. Thereafter, the second transferrer 412 takes the substrate 1 out of the second processor 200B and then transfers the substrate 1 to the third processor 200C. During this time, since the ambient atmosphere of the substrate 1 can be maintained at the vacuum atmosphere, deterioration of the blocking performance of the SAM 17 can be suppressed.

Subsequently, the third processor 200C performs step S105. Thereafter, the second transferrer 412 takes the substrate 1 out of the third processor 200C and then transfers the substrate 1 to the fourth processor 200D. During this time, since the ambient atmosphere of the substrate 1 can be maintained at the vacuum atmosphere, unintended oxidation of the substrate 1 can be suppressed.

Subsequently, the fourth processor 200D performs step S106. Thereafter, the controller 500 checks whether steps S104 to S106 have been executed the set number of times (N times). When the execution number has not reached the set number of times (N times), the second transferrer 412 takes the substrate 1 out of the fourth processor 200D and then transfers the substrate 1 to the second processor 200B. The controller 500 then controls the second processor 200B, the third processor 200C, the fourth processor 200D, and the transfer portion 400 to perform steps S104 to S106 again.

On the other hand, when the execution number has reached the set number of times (N times), the second transferrer 412 takes the substrate 1 out of the fourth processor 200D, transfers the substrate 1 to the load lock chamber 421, and then is retracted from the load lock chamber 421. Subsequently, the internal atmosphere of the load lock chamber 421 is switched from the vacuum atmosphere to atmospheric atmosphere. Thereafter, the first transferrer 402 takes the substrate 1 out of the load lock chamber 421 and then accommodates the substrate 1 in the carrier C. Thus, processing of the substrate 1 ends.

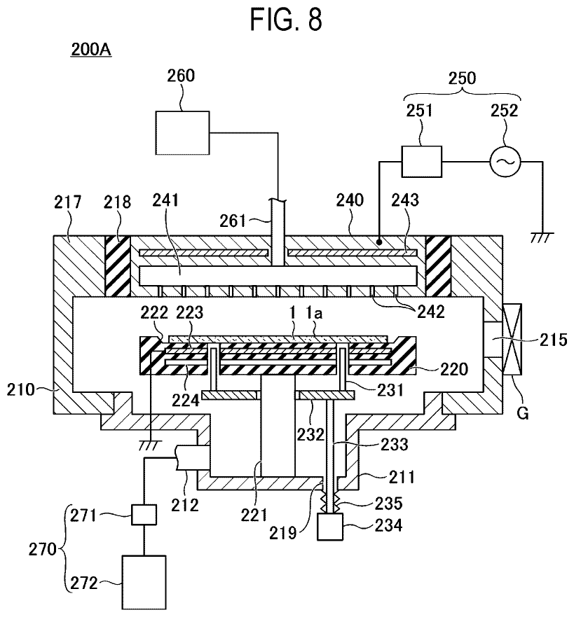

Next, the first processor 200A will be described with reference to FIG. 8. Since the second processor 200B, the third processor 200C, and the fourth processor 200D have the same configuration as the first processor 200A, illustration and description thereof will be omitted.

The first processor 200A includes a processing container 210 that is substantially cylindrical and airtight. An exhaust chamber 211 is provided at a center portion of a bottom wall of the processing container 210. The exhaust chamber 211 is, for example, a substantially cylindrical and protrudes downward. An exhaust pipe 212 is connected to the exhaust chamber 211, for example, at a side surface of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured so that an interior of the processing container 210 can be depressurized by the exhaust source 272. The pressure controller 271 and the exhaust source 272 constitute a gas discharger 270 that discharges a gas from the interior of the processing container 210.

A transfer port 215 is provided at a side surface of the processing container 210. The transfer port 215 is opened and closed by a gate valve G. The substrate 1 is loaded and unloaded between the interior of the processing container 210 and the second transfer chamber 411 (see FIG. 7) via the transfer port 215.

A stage 220, which is a holder for holding the substrate 1, is provided inside the processing container 210. The stage 220 holds the substrate 1 horizontally with the substrate surface 1a facing upward. The stage 220 is formed in a substantially circular shape in a plan view and is supported by a support 221. A recess 222 having a substantially circular shape is formed in a surface of the stage 220 to place the substrate 1 having a diameter of, for example, 300 mm, on the stage 220. An internal diameter of the recess 222 is slightly larger than the diameter of the substrate 1. A depth of the recess 222 is substantially the same as, for example, a thickness of the substrate 1. The stage 220 is made of, for example, a ceramic material such as aluminum nitride (AlN). The stage 220 may also be made of a metallic material such as nickel (Ni). Instead of the recess 222, a guide ring that guides the substrate 1 may be provided at a peripheral edge of the surface of the stage 220.

In the stage 220, for example, a grounded lower electrode 223 is embedded. A heater 224 is embedded below the lower electrode 223. The heater 224 is supplied with power from a power supply (not shown) based on a control signal from the controller 500 (see FIG. 7), thereby heating the substrate 1 placed on the stage 220 to a set temperature. When the entire stage 220 is made of a metal, the entire stage 220 functions as a lower electrode, and thus it is not necessary to embed the lower electrode 223 in the stage 220. The stage 220 is provided with a plurality (e.g., three) of lifting pins 231 for holding and lifting the substrate 1 placed on the stage 220. The lifting pins 231 may be made of, for example, a ceramic material such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219 for the lifting shaft 233, which is formed in a bottom surface of the exhaust chamber 211, and the lifting mechanism 234. The support plate 232 may be shaped so that the support plate 232 can be raised and lowered without interfering with the support 221 of the stage 220. The lifting pins 231 are configured to be raised and lowered between a position above the surface of the stage 220 and a position below the surface of the stage 220 by the lifting mechanism 234.

A gas supply 240 is provided in a ceiling wall 217 of the processing container 210 via an insulator 218. The gas supply 240 constitutes an upper electrode and faces the lower electrode 223. A radio-frequency power supply 252 is connected to the gas supply 240 via a matcher 251. By supplying radio-frequency power of 450 kHz to 100 MHz from the radio-frequency power supply 252 to the upper electrode (gas supply 240), a radio-frequency electric field is generated between the upper electrode (gas supply 240) and the lower electrode 223 to generate capacitively coupled plasma. A plasma generator 250 for generating plasma includes the matcher 251 and the radio-frequency power supply 252. The plasma generator 250 may generate other types of plasma, such as inductively coupled plasma, without being limited to the capacitively coupled plasma. In a process without generating plasma (e.g., step S104), the gas supply 240 does not need to constitute the upper electrode, and thus the lower electrode 223 is also unnecessary.

The gas supply 240 includes a hollow gas supply chamber 241. A plurality of holes 242 for distributively supplying a process gas into the processing container 210 is disposed, for example, uniformly, in a bottom surface of the gas supply chamber 241. In the gas supply 240, a heater 243 is embedded, for example, above the gas supply chamber 241. The heater 243 is supplied with power from a power supply (not shown) based on a control signal from the controller 500, thereby being heated to a set temperature.

A gas supplier 260 is connected to the gas supply chamber 241 via a gas supply path 261. The gas supplier 260 supplies gases used in at least one of steps S102 to S106 in FIG. 1 to the gas supply chamber 241 via the gas supply path 261. Although not shown, the gas supplier 260 includes an individual pipe for each gas type, an opening and closing valve provided in the individual pipe, and a flow rate controller provided in the individual pipe. When the individual pipe is opened by the opening and closing valve, a gas is supplied from a supply source to the gas supply path 261. A supply amount of the gas is controlled by the flow rate controller. On the other hand, when the individual pipe is closed by the opening and closing valve, the supply of the gas from the supply source to the gas supply path 261 is stopped.

### Examples

Next, experimental data will be described. First, Examples 1 to 3 will be described with reference to Table 1. In Examples 1 to 3, a substrate having a low-k film and a Cu film in different regions of a surface of the substrate was prepared, and the substrate was processed under conditions shown in Table 1. Examples 1 and 2 are comparative examples, and Example 3 is an embodiment of the present disclosure.

TABLE 1

| | | Example 1 | Example 2 | Example 3 |
|---|---|---|---|---|
| Conditions | S102 | Plasmarized (H₂ + N₂): 15 seconds, O₂: 30 seconds, PFBA | | |
| | S103 | Plasmarized H₂: 30 seconds | | |
| | S104 | HT: 60 seconds | | |
| | S105a | TMA: 10 seconds | | |
| | S105b | Not performed | | Plasmarized H₂: |
| | | | | 30 seconds |
| | S105c | TPSOL: 15 seconds | | |
| | S105d | K = 1 | | |
| | S106a | Not performed | (HF + NH₃): | Not performed |
| | | | 7 seconds | |
| | S106b | H₂O: 10 seconds | | |
| | S106c | Plasmarized H₂: 30 seconds | | |
| | S106d | M = 6 | M = 3 | |
| | S107 | N = 2 | N = 3 | N = 2 |
| SiO film | Film thickness | 12.7 | 12.3 | — |
| | [nm] | | | |
| | Opening width | 0 | 12.42 | 11.18 |
| | [nm] | | | |

In Examples 1 to 3, steps S102 to S104 had the same conditions. In step S102, a plasmarized and mixed gas containing H₂ gas and N₂ gas was supplied for 15 seconds, O₂ gas was supplied for 30 seconds, and then PFBA gas was supplied. In step S103, plasmarized H₂ gas was supplied for 30 seconds. In step S104, an SAM was selectively formed on a surface of the Cu film by supplying HT gas for 60 seconds.

In Example 1, after steps S102 to S104, steps S105a and S105c were performed, steps S106b and S106c were repeatedly performed six times. In step S105a, TMA gas was supplied for 10 seconds. In step S105c, TPSOL gas was supplied for 15 seconds. In step S106b, H₂O gas was supplied for 10 seconds. In step S106c, plasmarized H₂ gas was supplied for 30 seconds. Steps S105b and S106a were not performed. In Example 1, the set number of times (M times) for step S106d was six, and the set number of times (N times) for step S107 was two. In addition, since step S106a was not performed, the set number of times (L times) for step S106e was zero.

In Example 2, after steps S102 to S104, steps S105a and S105c were performed, step S106a was performed using a mixed gas of HF gas and NH₃ gas, and subsequently steps S106b and S106c were repeatedly performed three times. In step S106a, the mixed gas of HF gas and NH₃ gas was supplied for 7 seconds. Step S105b was not performed. In Example 2, the set number of times (M times) for step S106d was three, the set number of times (L times) for step S106e was one, and the set number of times (N times) for step S107 was three.

In Example 2, the number of times (N times) for step S107 was set to be three in order to make a film thickness of the SiO film obtained in Example 2 approximately the same as film thicknesses of the SiO films obtained in Examples 1 and 3.

In Example 3, after steps S102 to S104, steps S105a, S105b, and S105c were performed. In step S105b, plasmarized H₂ gas was supplied for 30 seconds. Steps S106a, S106b, and S106c were not performed. In Example 3, the set number of times (N times) for step S107 was two.

As is apparent from comparing opening widths of the SiO films obtained in Examples 1, 2, and 3 and shown in Table 1, it can be recognized that by performing step S105b after step S105a and before step S105c, a sufficient opening width can be obtained even when step S106 is not performed.

As is apparent from comparing the opening widths of the SiO films obtained in Examples 1 and 2 and shown in Table 1, it can be recognized that an opening width of a SiO film can be increased by performing all of steps S106a, S106b, and S106c.

Next, Examples 4 and 5 will be described. In Examples 4 and 5, a substrate having a Cu film formed over an entire surface of a silicon wafer was prepared, and the substrate was processed under conditions shown in Table 2. Examples 4 and 5 are reference examples. In Example 4, only steps S102 to S104 were performed, whereas in Example 5, steps S105a and S105b were performed after steps S102 to S104.

TABLE 2

| | | Example 4 | Example 5 |
|---|---|---|---|
| Conditions | S102 | Plasmarized (H₂ + N₂): 15 seconds, O₂: 30 seconds, PFBA | |
| | S103 | Plasmarized H₂: 30 seconds | |
| | S104 | HT: 60 seconds | |
| | S105a | Not performed | TMA: 10 seconds |
| | S106b | Not performed | Plasmarized H₂: 30 seconds |

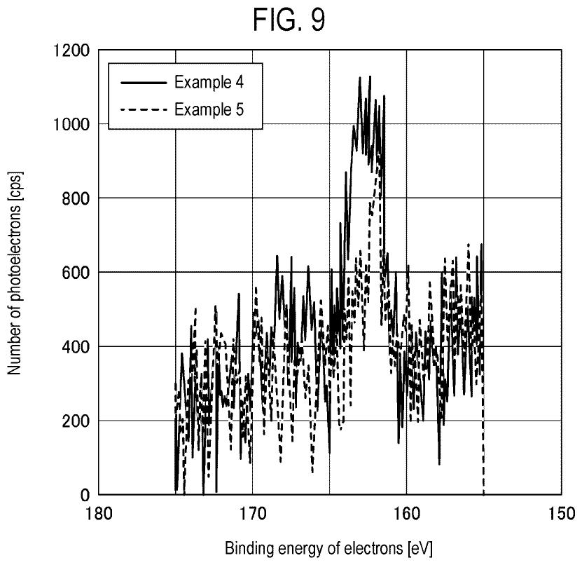

FIG. 9 illustrates X-ray photoelectron spectroscopy (XPS) spectra of surfaces of the substrates obtained in Examples 4 and 5. From FIG. 9, it can be recognized that even after performing step S105b, a peak of S2p contained in the SAM is observed and the SAM remains.

According to some embodiments of the present disclosure, when forming a target film by using a metal catalyst-containing gas and a silanol group-containing gas, it is possible to selectively form the target film in a desired region.

While certain embodiments of the film forming method and the film forming apparatus according to the present disclosure have been described, these embodiments have been presented by way of example only, and are not intended to limit the scope of the disclosure. Indeed, the embodiments described herein may be embodied in a variety of other forms. Furthermore, changes, modifications, substitutions, additions, deletions, and combinations in the form of the embodiments described herein may be made without departing from the spirit of the disclosure. The accompanying claims and their equivalents are intended to cover such forms or modifications as would fall within the scope and spirit of the disclosure.

What is claimed is:

1. A film forming method comprising:
(A) preparing a substrate having a first film and a second film made of a material different from that of the first film, in different regions of a surface of the substrate;
(B) selectively forming a film-formation inhibiting film that inhibits formation of a target film on a surface of the second film relative to a surface of the first film; and
(C) selectively forming the target film on the surface of the first film relative to the surface of the second film by using the film-formation inhibiting film,
wherein the target film includes at least silicon (Si) and oxygen (O), and
wherein (C) further comprises:
(Ca) supplying a metal catalyst-containing gas to the surface of the substrate to adsorb metal catalysts to the surface of the first film;
(Cb) after (Ca), supplying a plasmarized gas to the surface of the substrate to remove at least a portion of the metal catalysts adsorbed to a surface of the film-formation inhibiting film in (Ca); and
(Cc) after (Cb), supplying a silanol group-containing gas to the surface of the substrate.

2. The film forming method of claim 1, wherein the first film is an insulating film and the second film is a conductive film.

3. The film forming method of claim 2, wherein the film-formation inhibiting film is a self-assembled monolayer.

4. The film forming method of claim 3, wherein the self-assembled monolayer remains on the surface of the second film after (Cb) and before (Cc).

5. The film forming method of claim 1, wherein the film-formation inhibiting film is a graphene-containing film.

6. The film forming method of claim 1, wherein (Ca), (Cb), and (Cc) are repeatedly performed a plurality of times.

7. The film forming method of claim 1, wherein the plasmarized gas in (Cb) includes H₂ gas, a noble gas, or a mixed gas of H₂ gas and a noble gas.

8. The film forming method of claim 1, wherein (B) and (C) are repeatedly performed a plurality of times.

9. The film forming method of claim 1, further comprising:
(D) after (C), etching the target film which protrudes laterally from the surface of the first film.

10. The film forming method of claim 9, wherein (B), (C), and (D) are repeatedly performed a plurality of times.

11. The film forming method of claim 1, wherein the film-formation inhibiting film is a self-assembled monolayer.

12. A film forming apparatus comprising:
a processing container;
a holder configured to hold a substrate inside the processing container;
a gas supplier configured to supply a gas to an interior of the processing container;
a plasma generator configured to plasmarize the gas supplied to the interior of the processing container,
a gas discharger configured to discharge a gas from the interior of the processing container,
a transferrer configured to load and unload the substrate with respect to the processing container; and
a controller configured to control the gas supplier, the plasma generator, the gas discharger, and the transferrer to perform the film forming method of claim 1.
